(19) United States
(12) Patent Application Publication
(10) Pub. No.: US 2015/0171970 A1
(43) Pub. Date: Jun. 18, 2015

(54) SHORT OPTICAL PULSE GENERATOR, TERAHERTZ WAVE GENERATOR, CAMERA, IMAGING APPARATUS, AND MEASUREMENT APPARATUS

(71) Applicant: SEIKO EPSON CORPORATION, Tokyo (JP)

(72) Inventor: Hitoshi NAKAYAMA, Chino-shi (JP)

(21) Appl. No.: 14/574,202

(22) Filed: Dec. 17, 2014

(30) Foreign Application Priority Data
Dec. 18, 2013 (JP) 2013-261359

(51) Int. Cl. H04B 10/508; H01S 5/34

(52) U.S. Cl. CPC H04B 10/508; H01S 5/34

(57) ABSTRACT

A short optical pulse generator includes: an optical pulse generation unit which generates an optical pulse; a semiconductor saturable absorption mirror which has a multilayer film mirror and a quantum well structure and reflects the optical pulse; and a group velocity dispersion unit which produces a group velocity difference according to wavelength in the optical pulse reflected by the semiconductor saturable absorption mirror.

### BACKGROUND

1. Technical Field

The present invention relates to a short optical pulse generator, a terahertz wave generator, a camera, an imaging apparatus, and a measurement apparatus.

2. Related Art

In recent years, a terahertz wave which is an electromagnetic wave having a frequency equal to or greater than 100 GHz and equal to or less than 30 THz has been attracting attention. The terahertz wave can be used in, for example, imaging, various measurements, such as spectroscopic measurement, nondestructive inspection, and the like.

A terahertz wave generator which generates the terahertz wave has, for example, a short optical pulse generator which generates an optical pulse having a pulse width of about a subpicosecond (hundreds of femtoseconds), and a photoconductive antenna which generates a terahertz wave when irradiated with the optical pulse generated by the short optical pulse generator. In general, as the short optical pulse generator which generates an optical pulse having a pulse width of about a subpicosecond, a femtosecond fiber laser, a titanium sapphire laser, a semiconductor laser, or the like is used.

For example, JP-A-11-40889 describes an optical pulse generator which directly modulates a semiconductor laser to chirp the frequency of an optical pulse and then compresses a pulse width by an optical pulse compression unit (group velocity dispersion unit) having a fiber.

However, in the optical pulse generator of JP-A-11-40889, since the semiconductor laser is directly modulated to chirp the frequency of the optical pulse, the chirp quantity is small, and the pulse width cannot be sufficiently compressed in the group velocity dispersion unit.

### SUMMARY

An advantage of some aspects of the invention is to provide a short optical pulse generator capable of generating an optical pulse with a small pulse width. Another advantage of some aspects of the invention is to provide a terahertz wave generator, a camera, an imaging apparatus, and a measurement apparatus including the short optical pulse generator.

A short optical pulse generator according to an aspect of the invention includes an optical pulse generation unit which generates an optical pulse, a semiconductor saturable absorption mirror which has a multilayer film mirror and a quantum well structure and reflects the optical pulse, and a group velocity dispersion unit which produces a group velocity difference according to wavelength in the optical pulse reflected by the semiconductor saturable absorption mirror.

In the short optical pulse generator, the semiconductor saturable absorption mirror can chirp the frequency of the optical pulse passing through a quantum well layer. Accordingly, the short optical pulse generator can increase the chirp quantity of the optical pulse and can sufficiently compress the pulse width in the group velocity dispersion unit, for example, compared to a case where there is no semiconductor saturable absorption mirror. Therefore, the short optical pulse generator can generate an optical pulse with a small pulse width.

The short optical pulse generator according to the aspect of the invention may further include an electrode which applies a reverse bias to the semiconductor saturable absorption mirror.

In the short optical pulse generator with this configuration, it is possible to control the absorption characteristic of the semiconductor saturable absorption mirror and to adjust the chirp quantity of the frequency.

In the short optical pulse generator according to the aspect of the invention, two semiconductor saturable absorption mirrors may be provided, the group velocity dispersion unit may be provided to be sandwiched between the two semiconductor saturable absorption mirrors, and the optical pulse incident on the group velocity dispersion unit may be reflected by the two semiconductor saturable absorption mirrors multiple times and may travel in the group velocity dispersion unit.

In the short optical pulse generator with this configuration, it is possible to repeat application of frequency chirp and pulse compression to the optical pulse. With this, it is possible to increase the chirp quantity of the optical pulse and a group velocity dispersion value to the optical pulse. Accordingly, the short optical pulse generator can generate an optical pulse with a smaller pulse width.

The short optical pulse generator according to the aspect of the invention may further include a variable mechanism which changes the incidence angle of the optical pulse to the semiconductor saturable absorption mirror.

In the short optical pulse generator with this configuration, it is possible to change the number of reflections of the optical pulse in the semiconductor saturable absorption mirror. As a result, in the short optical pulse generator, it is possible to change the chirp quantity of the optical pulse and the group velocity dispersion value of the group velocity dispersion unit and to change the pulse width of the optical pulse generated by the short optical pulse generator.

The short optical pulse generator according to the aspect of the invention may further include a collimator lens which converts the optical pulse incident on the group velocity dispersion unit to parallel light.

In the short optical pulse generator with this configuration, it is possible to suppress the spread of the optical pulse generated by the optical pulse generation unit.

In the short optical pulse generator according to the aspect of the invention, the group velocity dispersion unit may be a glass substrate.

In the short optical pulse generator with this configuration, it is possible to achieve reduction in cost. The glass substrate does not extremely absorb the optical pulse generated by the optical pulse generation unit. For this reason, in the short optical pulse generator, it is possible to suppress a decrease in intensity of the optical pulse.

A terahertz wave generator according to another aspect of the invention includes the short optical pulse generator described above, and a photoconductive antenna which generates a terahertz wave when irradiated with a short optical pulse generated by the short optical pulse generator.

The terahertz wave generator can include the short optical pulse generator capable of generating an optical pulse with a small pulse width.

A camera according to still another aspect of the invention includes the short optical pulse generator described above, a photoconductive antenna which generates a terahertz wave when irradiated with a short optical pulse generated by the short optical pulse generator, a terahertz wave detection unit which detects the terahertz wave emitted from the photoconductive antenna and transmitted through an object or the terahertz wave reflected by the object, and a storage unit which stores the detection result of the terahertz wave detection unit.

The camera can include the short optical pulse generator capable of generating an optical pulse with a small pulse width.

An imaging apparatus according to yet another aspect of the invention includes the short optical pulse generator described above, a photoconductive antenna which generates a terahertz wave when irradiated with a short optical pulse generated by the short optical pulse generator, a terahertz wave detection unit which detects the terahertz wave emitted from the photoconductive antenna and transmitted through an object or the terahertz wave reflected by the object, and an image forming unit which forms the image of the object based on the detection result of the terahertz wave detection unit.

The imaging apparatus can include the short optical pulse generator capable of generating an optical pulse with a small pulse width.

A measurement apparatus according to still yet another aspect of the invention includes the short optical pulse generator described above, a photoconductive antenna which generates a terahertz wave when irradiated with a short optical pulse generated by the short optical pulse generator, a terahertz wave detection unit which detects the terahertz wave emitted from the photoconductive antenna and transmitted through an object or the terahertz wave reflected by the object, and a measurement unit which measures the object based on the detection result of the terahertz wave detection unit.

The measurement apparatus can include the short optical pulse generator capable of generating an optical pulse with a small pulse width.

### BRIEF DESCRIPTION OF THE DRAWINGS

The invention will be described with reference to the accompanying drawings, wherein like numbers reference like elements.

FIG. 1 is a diagram schematically showing the short optical pulse generator according to an embodiment.

FIG. 2 is a sectional view schematically showing a semiconductor saturable absorption mirror of the short optical pulse generator according to the embodiment.

FIG. 3 is a graph showing an example of an optical pulse generated by the optical pulse generation unit.

FIG. 4 is a graph showing an example of the chirp characteristic of the semiconductor saturable absorption mirror.

FIG. 5 is a graph showing an example of an optical pulse generated by a group velocity dispersion unit.

FIG. 6 is a graph showing an example of an optical pulse generated by the group velocity dispersion unit.

FIG. 7 is a sectional view schematically showing a semiconductor saturable absorption mirror of a short optical pulse generator according to a first modification example of the embodiment.

FIG. 8 is a diagram schematically showing a short optical pulse generator according to a second modification example of the embodiment.

FIG. 9 is a diagram schematically showing a model for describing the relationship of the incidence angle of an optical pulse to the semiconductor saturable absorption mirror, a chirp quantity, and a group velocity dispersion value.

FIG. 10 is a graph showing the relationship between the incidence angle of an optical pulse to the semiconductor saturable absorption mirror and the group velocity dispersion value.

FIG. 11 is a diagram showing the configuration of a terahertz wave generator according to the embodiment.

FIG. 12 is a block diagram showing an imaging apparatus according to the embodiment.

FIG. 13 is a plan view schematically showing a terahertz wave detection unit of the imaging apparatus according to the embodiment.

FIG. 14 is a graph showing a spectrum in a terahertz band of an object.

FIG. 15 is a diagram of an image representing the distribution of substances A, B, and C of an object.

FIG. 16 is a block diagram of a measurement apparatus according to the embodiment.

FIG. 17 is a block diagram showing a camera according to the embodiment.

FIG. 18 is a perspective view schematically showing the camera according to the embodiment.

### DESCRIPTION OF EXEMPLARY EMBODIMENTS

Hereinafter, a preferred embodiment of the invention will be described in detail referring to the drawings. It should be noted that the following embodiment is not intended to unduly limit the content of the invention described in the appended claims. The entire configuration described in the embodiment is not necessarily the essential components of the invention.

### 1. Short Optical Pulse Generator

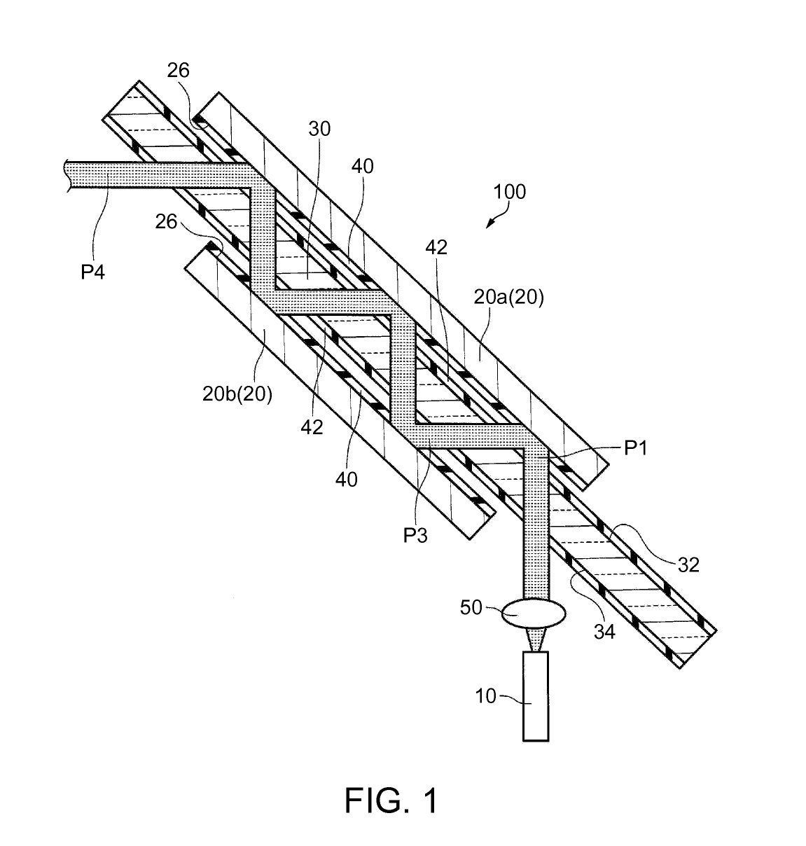

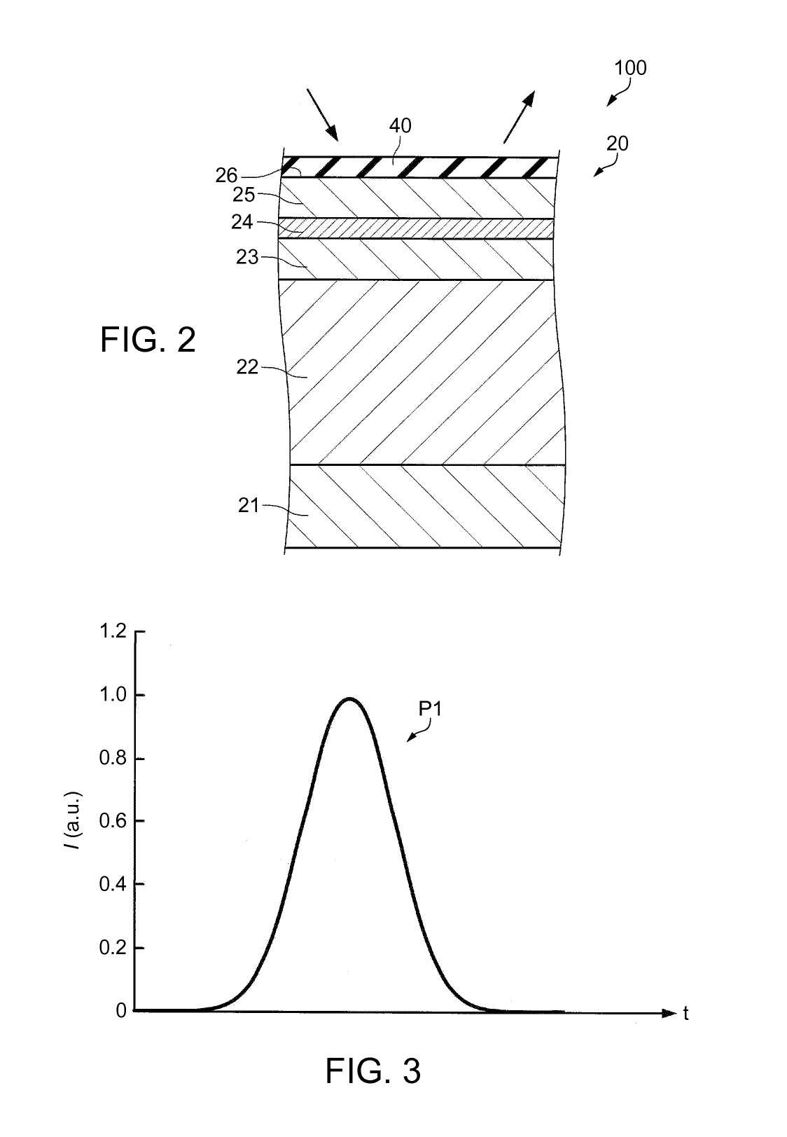

First, a short optical pulse generator according to an embodiment will be described referring to the drawings. FIG. 1 is a diagram schematically showing a short optical pulse generator 100 according to the embodiment. FIG. 2 is a sectional view schematically showing a semiconductor saturable absorption mirror 20 of the short optical pulse generator 100 according to the embodiment.

As shown in FIGS. 1 and 2, the short optical pulse generator 100 includes an optical pulse generation unit 10, a semiconductor saturable absorption mirror (SESAM) 20, a group velocity dispersion unit 30, antireflection films 40 and 42, and a collimator lens 50. It should be noted that, for convenience, in FIG. 1, the semiconductor saturable absorption mirror 20 is shown in a simplified form.

The optical pulse generation unit 10 generates an optical pulse. Here, the optical pulse refers to light whose intensity changes steeply in a short time. The pulse width (full width at half maximum FWHM) of the optical pulse generated by the optical pulse generation unit 10 is not particularly limited, and is, for example, equal to or greater than 1 ps (picosecond) and equal to or less than 100 ps. The optical pulse generation unit 10 is, for example, a semiconductor laser, a super luminescent diode (SLD), or the like.

The semiconductor saturable absorption mirror 20 chirps the frequency of the optical pulse generated by the optical pulse generation unit 10. The semiconductor saturable absorption mirror 20 is made of, for example, a semiconductor material, and has a quantum well structure. In the example shown in FIG. 2, the semiconductor saturable absorption mirror 20 has a quantum well layer 24 having a quantum well structure. If the optical pulse passes through the quantum well layer 24, the refractive index of the quantum well layer 24 changes by an optical Kerr effect, and the phase of an electric field is changed (self phase modulation effect). The frequency of the optical pulse is chirped by the self phase modulation effect. Here, the condition that the frequency is chirped means that the frequency of the optical pulse temporally changes.

The quantum well layer 24 of the semiconductor saturable absorption mirror 20 is made of a semiconductor material, and is thus low in response speed with respect to an optical pulse having a pulse width of about 1 ps to 100 ps. For this reason, in the quantum well layer 24, the frequency of the optical pulse is chirped (up-chirped or down-chirped) in proportion to the intensity (the square of electric field amplitude) of the optical pulse. Here, the up-chirp refers to a case where the frequency of the optical pulse increases with time, and the down-chirp refers to a case where the frequency of the optical pulse decreases with time. In other words, the up-chirp refers to a case where the wavelength of the optical pulse is shortened with time, and the down-chirp refers to a case where the wavelength of the optical pulse is lengthened with time.

As shown in FIG. 2, the semiconductor saturable absorption mirror 20 is a semiconductor element in which a multilayer film mirror 22 and the quantum well layer 24 are laminated on a support substrate 21, and the optical pulse passing through the quantum well layer 24 is reflected by the multilayer film mirror 22. Hereinafter, the specific configuration of the semiconductor saturable absorption mirror 20 will be described.

The semiconductor saturable absorption mirror 20 has a support substrate 21, a multilayer film mirror 22, a first layer 23, a quantum well layer 24, and a second layer 25. It should be noted that both or either of the first layer 23 and the second layer 25 may not be provided.

The support substrate 21 is, for example, a GaAs substrate.

The multilayer film mirror 22 is provided on the support substrate 21. The multilayer film mirror 22 is a distributed Bragg reflection (DBR) mirror in which a high refractive index layer (not shown) and a low refractive index layer (not shown) are alternately laminated. The high refractive index layer is, for example, a GaAs layer. The low refractive index layer is, for example, an AlAs layer. The multilayer film mirror 22 reflects the optical pulse incident on the semiconductor saturable absorption mirror 20. The optical pulse is obliquely incident on the upper surface (the surface in contact with the first layer 23) of the multilayer film mirror 22.

The first layer 23 is provided on the multilayer film mirror 22. The first layer 23 functions as, for example, a buffer layer, and is an AlGaAs layer. The optical pulse incident on the semiconductor saturable absorption mirror 20 can be transmitted through the first layer 23. The first layer 23 can relax lattice mismatching with respect to the multilayer film mirror 22 of the quantum well layer 24. It should be noted that the first layer 23 may not be a buffer layer or may be provided as a refractive index adjustment layer.

The quantum well layer 24 is provided on the first layer 23. The quantum well layer 24 has, for example, a multiquantum well structure in which a quantum well structure having a GaAs layer and an AlGaAs layer are stacked in three layers. The optical pulse incident on the semiconductor saturable absorption mirror 20 can be transmitted through the quantum well layer 24. As described above, the quantum well layer 24 chirps the frequency of the optical pulse passing through the quantum well layer 24. The quantum well layer 24 functions as, for example, a saturable absorber. That is, the quantum well layer 24 functions as an absorber with respect to incident light (pulse) with low intensity and functions as a transparent body with respect to incident light with high intensity while the ability as an absorber is saturated.

It should be noted that the quantum well structure indicates a general quantum well structure in the field of a semiconductor light emitting device, and is a structure in which a thin film (nm order) made of a material having a small band gap is sandwiched between thin films made of a material having a large band gap using two or more materials having different band gaps.

The second layer 25 is provided on the quantum well layer 24. The second layer 25 functions as, for example, a protective layer, and is an AlGaAs layer. The optical pulse incident on the semiconductor saturable absorption mirror 20 can be transmitted through the second layer 25. The second layer 25 can suppress sticking of a foreign substance or the like to the quantum well layer 24. A first antireflection film 40 is provided on an upper surface 26 of the second layer 25. It should be noted that the second layer 25 may not be a protective layer or may be provided as a refractive index adjustment layer.

As shown in FIG. 1, two semiconductor saturable absorption mirrors 20 (first semiconductor saturable absorption mirror 20a and second semiconductor saturable absorption mirror 20b) are provided. The semiconductor saturable absorption mirrors 20a and 20b are arranged such that the second layers 25 (specifically, the upper surfaces 26 of the second layers 25) face each other with the group velocity dispersion unit 30 sandwiched therebetween. That is, the upper surface (the surface in contact with the first antireflection film 40) 26 of the second layer 25 of the first semiconductor saturable absorption mirror 20a and the upper surface 26 of the second layer 25 of the second semiconductor saturable absorption mirror 20b face each other with the group velocity dispersion unit 30 sandwiched therebetween. In the example shown in the drawing, the optical pulse generated by the optical pulse generation unit is incident on the first semiconductor saturable absorption mirror 20a earlier than the second semiconductor saturable absorption mirror 20b.

The group velocity dispersion unit 30 produces a group velocity difference according to wavelength (frequency) for the optical pulse (that is, the optical pulse subjected to frequency chirp) reflected by the semiconductor saturable absorption mirror 20. Specifically, the group velocity dispersion unit 30 can produce a group velocity difference to make the pulse width of the optical pulse small for the optical pulse subjected to frequency chirp (pulse compression).

The group velocity dispersion unit 30 is, for example, a glass substrate, a GaN substrate, a SiC substrate, a plastic substrate, a sapphire substrate, or the like. In this case, the group velocity dispersion unit 30 is a normal dispersion medium. Accordingly, the group velocity dispersion unit 30 produces a positive group velocity dispersion in the down-chirped optical pulse, thereby making the pulse width small. In this way, the group velocity dispersion unit 30 performs pulse compression based on group velocity dispersion. It should be noted that group velocity dispersion refers to the phenomenon in which the propagation velocity of the optical pulse differs according to wavelength, and thus, the group velocity changes depending on frequency. The positive group velocity dispersion refers to the phenomenon in which the group velocity increases with an increase in wavelength. In other words, the positive group velocity dispersion refers to the phenomenon in which the group velocity increases with a decrease in frequency.

The group velocity dispersion unit 30 is provided to be sandwiched between the two semiconductor saturable absorption mirrors 20a and 20b. The optical pulse incident on the group velocity dispersion unit 30 is reflected by the two semiconductor saturable absorption mirrors 20a and 20b multiple times and travels in the group velocity dispersion unit 30. Here, “the optical pulse traveling in the group velocity dispersion unit 30” includes a case where the optical pulse constantly travels in the group velocity dispersion unit 30 and a case where, as shown in FIG. 1, the optical pulse is emitted from the group velocity dispersion unit 30 to the outside (air) and is incident on the group velocity dispersion unit 30 from the outside again. The number of reflections of the optical pulse in the semiconductor saturable absorption mirrors 20a and 20b is not particularly limited. The pulse width of the optical pulse which is compressed by the group velocity dispersion unit 30 and then emitted from the short optical pulse generator 100 is not particularly limited, and is, for example, equal to or greater than 1 fs (femtosecond) and equal to or less than 800 fs.

The group velocity dispersion unit 30 has a first surface 32, and a second surface 34 opposite to the first surface 32. The first surface 32 and the second surface 34 face the upper surface 26 of the second layer 25 of the semiconductor saturable absorption mirror 20. The first surface 32 and the second surface 34 are the surfaces through which the optical pulse is incident and the optical pulse is emitted in the group velocity dispersion unit 30. The thickness of the group velocity dispersion unit 30 (the distance between the first surface 32 and the second surface 34) is not particularly limited, and is, for example, equal to or greater than 100 μm and equal to or less than 20 mm.

The first antireflection film 40 is provided on the surface through which the optical pulse is incident and the optical pulse is emitted in the semiconductor saturable absorption mirror 20. Specifically, the first antireflection film 40 is provided on (the upper surface 26 of) the second layer 25 of the semiconductor saturable absorption mirror 20. The first antireflection film. 40 is, for example, a SiO₂ layer, a Ta₂O₅ layer, an Al₂O₃ layer, a TiN layer, a TiO₂ layer, a SiON layer, a SiN layer, or a multilayer film thereof. The first antireflection film 40 can reduce the reflectance of the optical pulse on the upper surface 26.

The second antireflection film 42 is provided on the first surface 32 and the second surface 34 of the group velocity dispersion unit 30. The second antireflection film 42 is, for example, a SiO₂ layer, a Ta₂O₅ layer, an Al₂O₃ layer, a TiN layer, a TiO₂ layer, a SiON layer, a SiN layer, or a multilayer film thereof. The second antireflection film 42 can reduce the reflectance of the optical pulse on the surfaces 32 and 34.

It should be noted that, in the example shown in FIG. 1, although the first antireflection film 40 and the second antireflection film 42 are separated from each other, the first antireflection film 40 and the second antireflection film 42 may be in contact with each other. With this, it is possible to achieve reduction in size of the short optical pulse generator 100. Furthermore, it is possible to suppress sticking of a foreign substance to the surfaces of the antireflection films 40 and 42.

The collimator lens 50 is provided between the optical pulse generation unit 10 and the group velocity dispersion unit 30. The material of the collimator lens 50 is, for example, glass. The optical pulse generated by the optical pulse generation unit 10 is incident on the collimator lens 50. The collimator lens 50 can convert the optical pulse incident on the group velocity dispersion unit 30 to parallel light.

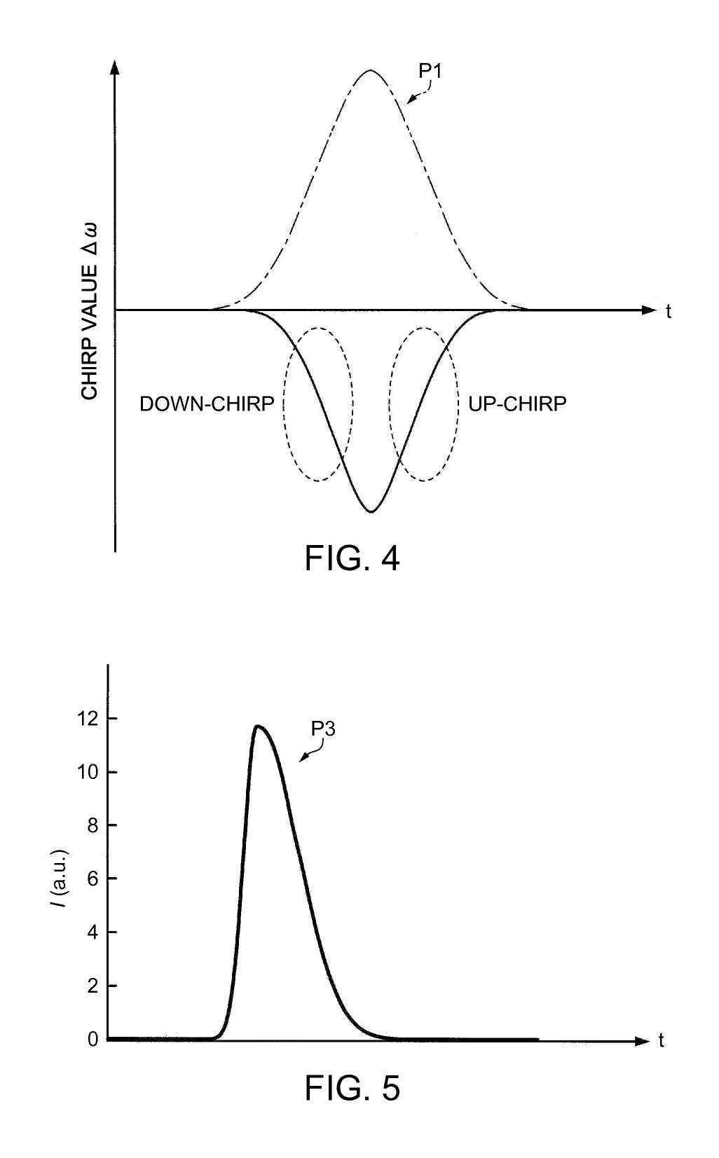

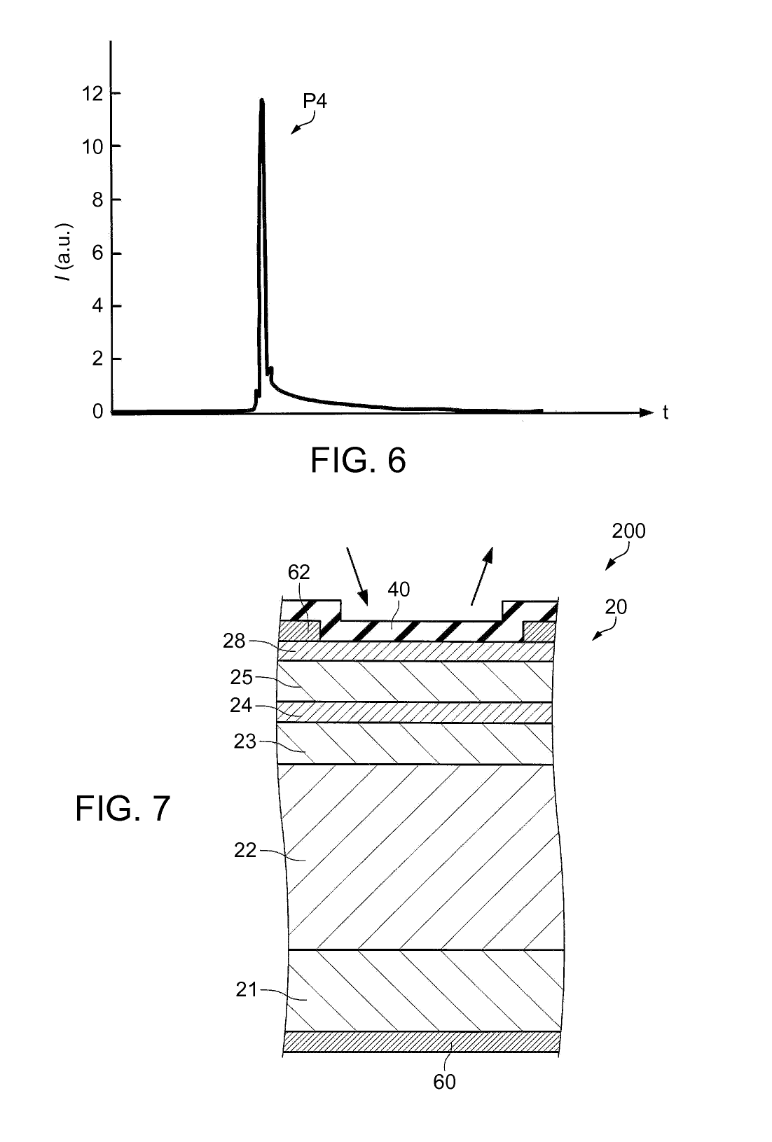

Next, the operation of the short optical pulse generator 100 will be described. FIG. 3 is a graph showing an example of an optical pulse P1 generated by the optical pulse generation unit 10. FIG. 4 is a graph showing an example of the chirp characteristic of the semiconductor saturable absorption mirror 20. FIG. 5 is a graph showing an example of an optical pulse P3 generated by the group velocity dispersion unit 30. FIG. 6 is a graph showing an example of an optical pulse P4 generated by the group velocity dispersion unit 30.

It should be noted that, as shown in FIG. 1, the optical pulse P1 shown in FIG. 3 is an optical pulse after being emitted from the optical pulse generation unit 10 and passing through the collimator lens 50 and the group velocity dispersion unit 30 and before being incident on the first semiconductor saturable absorption mirror 20a. The optical pulse P3 shown in FIG. 5 is an optical pulse before being incident on the second semiconductor saturable absorption mirror 20b after the optical pulse P1 is reflected by the first semiconductor saturable absorption mirror 20a and passes through the group velocity dispersion unit 30. The optical pulse P4 shown in FIG. 6 is an optical pulse which is emitted from the group velocity dispersion unit 30 (emitted from the short optical pulse generator 100) after the optical pulse P3 passes through the group velocity dispersion unit 30 while being reflected between the semiconductor saturable absorption mirrors 20a and 20b multiple times.

In the graph shown in FIG. 3, the horizontal axis t represents time and the vertical axis I represents light intensity (in proportion to the square of electric field amplitude). In the graph shown in FIG. 4, the horizontal axis t represents time and the vertical axis Δω represents a chirp quantity (variation in frequency). In FIG. 4, the optical pulse P1 is indicated by a one-dot-chain line and the chirp quantity Δω corresponding to the optical pulse P1 is indicated by a solid line. In the graphs shown in FIGS. 5 and 6, the horizontal axis t represents time and the vertical axis I represents light intensity. The graphs shown in FIGS. 5 and 6 correspond to the graph shown in FIG. 3.

As shown in FIG. 3, the optical pulse P1 generated by the optical pulse generation unit 10 is, for example, a Gaussian waveform. In the example shown in the drawing, the pulse width (full width at half maximum FWHM) t of the optical pulse P1 is 10 ps. The optical pulse P1 which is generated by the optical pulse generation unit 10 and passes through the group velocity dispersion unit 30 is incident on the first semiconductor saturable absorption mirror 20a (see FIG. 1). The optical pulse P1 incident on the first semiconductor saturable absorption mirror 20a passes through the second layer 25, the quantum well layer 24, and the first layer 23, is reflected by the multilayer film mirror 22, passes through the first layer 23, the quantum well layer 24, and the second layer 25 again, and is emitted from the first semiconductor saturable absorption mirror 20a.

The quantum well layer 24 of the semiconductor saturable absorption mirror 20 has a chirp characteristic proportional to light intensity. Expression (1) is an expression representing the effect of frequency chirp.

$$Δω = - \frac{{n}_{2} l {ω}_{0}}{2 c {τ}_{r}} {\vert E \vert}^{2} \qquad ( 1 )$$

Here, Δω is a chirp quantity (variation in frequency), c is a light speed, τᵣ is a response time of a nonlinear refractive index effect, n₂ is a nonlinear refractive index, l is a moving distance when an optical pulse passes through the quantum well layer 24, ω₀ is an initial frequency, and E is amplitude of an electric field.

The quantum well layer 24 of the semiconductor saturable absorption mirror 20 applies frequency chirp represented by Expression (1) to the optical pulse P1 passing through the quantum well layer 24. Specifically, as shown in FIG. 4, for the optical pulse P1, the quantum well layer 24 decreases the frequency with time in the front portion of the optical pulse P1 and increases the frequency with time in the rear portion of the optical pulse P1. That is, the quantum well layer 24 down-chirps the front portion of the optical pulse P1 and up-chirps the rear portion of the optical pulse P1. Accordingly, the optical pulse P1 passes through the quantum well layer 24 and becomes an optical pulse (hereinafter, referred to as “optical pulse P2”) in which the front portion is down-chirped and the rear portion is up-chirped. The chirped optical pulse P2 (not shown) is incident on the group velocity dispersion unit 30.

The group velocity dispersion unit 30 produces a group velocity difference according to wavelength (frequency) for the chirped optical pulse P2 (group velocity dispersion) to perform pulse compression. Specifically, the group velocity dispersion unit 30 produces a positive group velocity dispersion in the optical pulse P2 to compress the front portion of the down-chirped optical pulse P2. With this, as shown in FIG. 5, the optical pulse P3 is generated. The pulse width of the optical pulse P3 is smaller than the pulse width of the optical pulse P1. The optical pulse P3 emitted from the group velocity dispersion unit 30 is incident on the second semiconductor saturable absorption mirror 20b. Then, the frequency of the optical pulse P3 is chirped in the quantum well layer 24 of the second semiconductor saturable absorption mirror 20b.

As described above, the optical pulse passes through the group velocity dispersion unit 30 while being reflected between the semiconductor saturable absorption mirrors 20a and 20b multiple times. That is, in the short optical pulse generator 100, application of frequency chirp and pulse compression are repeated for the optical pulse. The pulse width of the optical pulse becomes smaller each time application of frequency chirp and pulse compression are repeated. That is, when the number of reflections between the semiconductor saturable absorption mirrors 20a and 20b is large, the chirp quantity applied to the optical pulse is large, and a large group velocity difference of the optical pulse is produced. Then, as shown in FIG. 6, the short optical pulse generator 100 emits the optical pulse P4 whose pulse width becomes small with multiple reflections. In the example shown in the drawing, the pulse width t of the optical pulse P4 is 0.33 ps.

For example, the short optical pulse generator 100 has the following feature.

The short optical pulse generator 100 includes the semiconductor saturable absorption mirror 20 which has the multilayer film mirror 22 and the quantum well structure and reflects the optical pulse, and the group velocity dispersion unit 30 which produces the group velocity difference according to wavelength in the optical pulse reflected by the semiconductor saturable absorption mirror 20. The semiconductor saturable absorption mirror 20 can chirp the frequency of the optical pulse passing through the quantum well layer 24. Accordingly, the short optical pulse generator 100 can increase the chirp quantity of the optical pulse and can sufficiently compress the pulse width in the group velocity dispersion unit 30, for example, compared to a form in which there is no semiconductor saturable absorption mirror. Therefore, the short optical pulse generator 100 can generate an optical pulse with a small pulse width.

In the short optical pulse generator 100, the optical pulse incident on the group velocity dispersion unit 30 is reflected by the two semiconductor saturable absorption mirrors 20a and 20b multiple times and travels in the group velocity dispersion unit 30. For this reason, in the short optical pulse generator 100, it is possible to repeat application of frequency chirp and pulse compression for the optical pulse. With this, it is possible to increase the chirp quantity of the optical pulse and the group velocity dispersion value of the group velocity dispersion unit 30. Accordingly, the short optical pulse generator 100 can generate an optical pulse with a smaller pulse width.

The short optical pulse generator 100 includes the collimator lens 50 which converts the optical pulse incident on the group velocity dispersion unit 30 to parallel light. For this reason, in the short optical pulse generator 100, it is possible to suppress the spread of the optical pulse generated by the optical pulse generation unit 10.

In the short optical pulse generator 100, the group velocity dispersion unit 30 is a glass substrate. For this reason, it is possible to achieve reduction in cost of the short optical pulse generator 100. The glass substrate does not extremely absorb the optical pulse generated by the optical pulse generation unit 10. For this reason, in the short optical pulse generator 100, it is possible to suppress a decrease in intensity of the optical pulse.

### 2. Modification Examples of Short Optical Pulse Generator

### 2.1. First Modification Example

Next, a short optical pulse generator according to a first modification example of the embodiment will be described referring to the drawings. FIG. 7 is a sectional view schematically showing a short optical pulse generator 200 according to the first modification example of the embodiment, and corresponds to FIG. 2.

Hereinafter, in the short optical pulse generator 200 according to the first modification example of the embodiment, a difference from the example of the short optical pulse generator 100 according to the embodiment will be described, and description of the same points will not be repeated. The same applies to a short optical pulse generator according to a second modification example of the embodiment described below.

The short optical pulse generator 200 is different from the above-described short optical pulse generator 100 in that, as shown in FIG. 7, a first electrode 60 and a second electrode 62 are provided in the semiconductor saturable absorption mirror 20. The electrodes 60 and 62 are electrodes which are provided to apply a reverse bias to the semiconductor saturable absorption mirror 20 (specifically, to the quantum well layer 24).

The first electrode 60 is provided on the lower surface of the support substrate 21. As the first electrode 60, for example, an electrode in which a Cr layer, an AuGe layer, a Ni layer, and an Au layer are laminated is used. The second electrode 62 is provided on a contact layer 28 provided on the second layer 25. The second electrode 62 is provided except the region where the optical pulse is incident and the region where the optical pulse is emitted. As the second electrode 62, for example, an electrode in which a Cr layer, an AuZn layer, and an Au layer are laminated is used.

In the short optical pulse generator 200, the support substrate 21 is, for example, an n-type GaAs substrate. The multilayer film mirror 22 is an n-type DBR mirror. The first layer 23 is an n-type AlGaAs layer. The quantum well layer 24 is an i type. The second layer 25 is a p-type AlGaAs layer. The contact layer 28 is a p-type GaAs layer.

It should be noted that the electrodes 60 and 62 may be transparent electrodes made of indium tin oxide (ITO) or the like. In this case, though not shown, the second electrode 62 may be provided on the entire upper surface 26. In the example shown in the drawing, although the first antireflection film 40 is provided on the second electrode 62, the first antireflection film 40 may be provided only in the region of the upper surface 26 where the optical pulse is incident and the region of the upper surface 26 where the optical pulse is emitted.

As described above, the short optical pulse generator 200 includes the electrodes 60 and 62 which are provided to apply a reverse bias to the semiconductor saturable absorption mirror 20. For this reason, in the short optical pulse generator 200, it is possible to control the absorption characteristic of the quantum well layer 24 and to adjust the chirp quantity of the frequency.

### 2.2. Second Modification Example

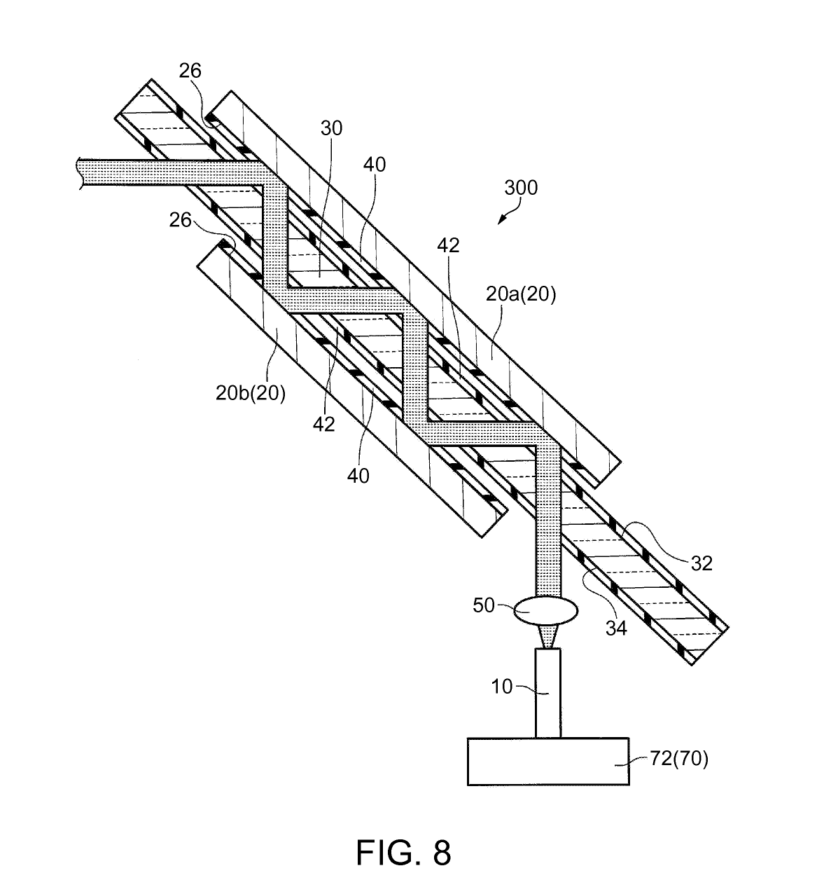

Next, a short optical pulse generator according to a second modification example of the embodiment will be described referring to the drawings. FIG. 8 is a diagram schematically showing a short optical pulse generator 300 according to the second modification example of the embodiment and corresponds to FIG. 1.

As shown in FIG. 8, the short optical pulse generator 300 is different from the above-described short optical pulse generator 100 in that a variable mechanism 70 which changes the incidence angle of the optical pulse to the semiconductor saturable absorption mirror 20 is provided.

For example, the variable mechanism 70 has a stage 72 on which the optical pulse generation unit 10 is placed, and a drive circuit (not shown) which drives (rotates) the stage 72. The stage 72 is rotatable based on a signal from the drive circuit. The rotation of the stage 72 allows the optical pulse generation unit 10 to rotate, whereby it is possible to change the incidence angle of the optical pulse to the semiconductor saturable absorption mirror 20.

It should be noted that the variable mechanism 70 is not limited to a form in which the optical pulse generation unit 10 is rotated, and a form may be made in which the semiconductor saturable absorption mirror 20 is rotated to change the incidence angle of the optical pulse to the semiconductor saturable absorption mirror 20. The variable mechanism 70 may rotate an optical element (not shown), such as a mirror which changes the travel direction of the optical pulse incident on the semiconductor saturable absorption mirror 20, thereby changing the incidence angle of the optical pulse to the semiconductor saturable absorption mirror 20.

The short optical pulse generator 300 may include the electrodes 60 and 62 which apply a reverse bias to the semiconductor saturable absorption mirror 20 as shown in FIG. 7, or may not include the electrodes as shown in FIG. 2.

As described above, the short optical pulse generator 300 includes the variable mechanism 70 which changes the incidence angle of the optical pulse to the semiconductor saturable absorption mirror 20. With this, in the short optical pulse generator 300, it is possible to change the number of reflections of the optical pulse in the semiconductor saturable absorption mirror 20. As a result, in the short optical pulse generator 300, it is possible to change the chirp quantity of the optical pulse and the group velocity dispersion value of the group velocity dispersion unit 30, and to change the pulse width of the optical pulse generated by the short optical pulse generator 300.

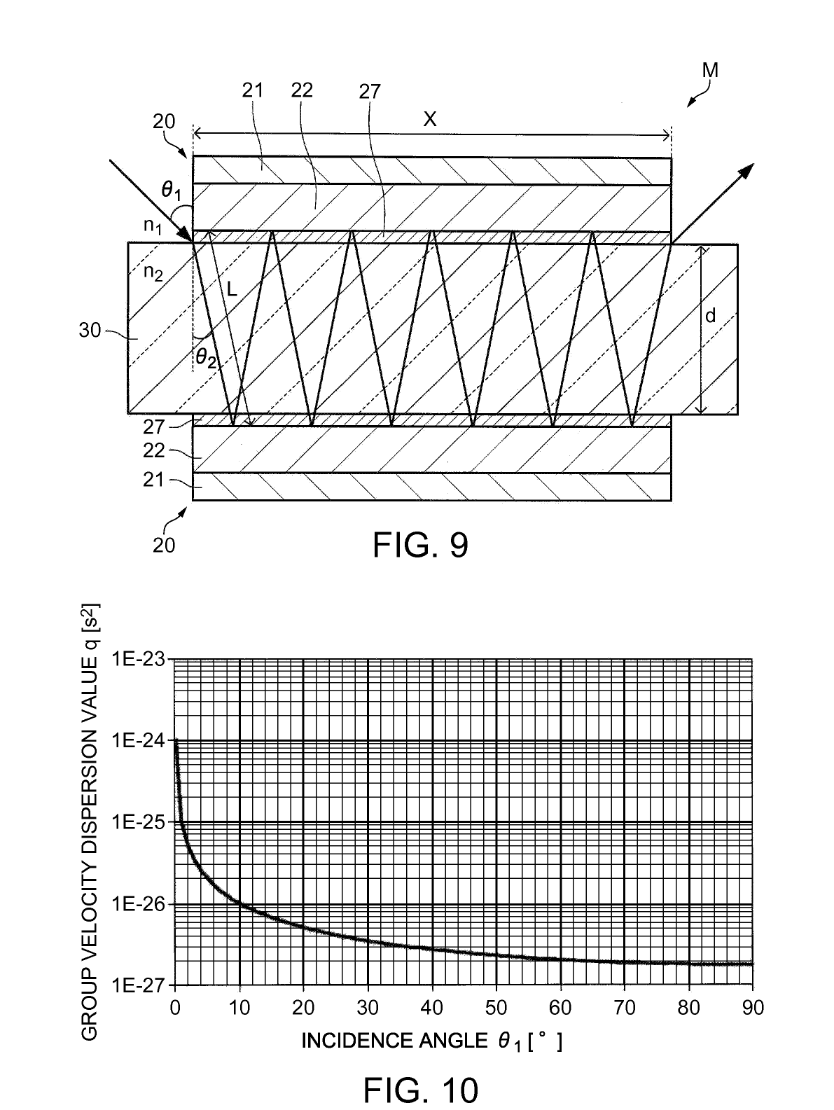

Hereinafter, the relationship of the incidence angle of the optical pulse to the semiconductor saturable absorption mirror 20, the chirp quantity, and the group velocity dispersion value will be described. FIG. 9 is a diagram schematically showing a model M for describing the relationship of the incidence angle of the optical pulse to the semiconductor saturable absorption mirror 20, the chirp quantity, and the group velocity dispersion value.

In the model M, as shown in FIG. 9, the incidence angle of the optical pulse generated by the optical pulse generation unit 10 when being incident on the group velocity dispersion unit 30 is represented as θ₁. The refraction angle of the optical pulse in the group velocity dispersion unit 30 is represented as θ₂. The refractive index of a medium (for example, air) before the optical pulse is incident on the group velocity dispersion unit 30 is represented as n₁. The refractive index of the group velocity dispersion unit 30 is represented as n₂. The length of the group velocity dispersion unit 30 (the length of the semiconductor saturable absorption mirror 20) is represented as X. The thickness of the group velocity dispersion unit 30 is represented as d. When the optical pulse travels in the group velocity dispersion unit while being reflected between the two semiconductor saturable absorption mirrors 20, a moving distance of the optical pulse from the multilayer film mirror 22 of one semiconductor saturable absorption mirror 20 to the multilayer film mirror 22 of the other semiconductor saturable absorption mirror 20 is represented as L.

In the model M shown in FIG. 9, the number of reflections necessary for obtaining a desired group velocity dispersion value is calculated. First, Expression (2) is established by Snell's law.

n₁ sin θ₁=n₂ sin θ₂ (2)

If Expression (2) is used, the distance L is expressed as Expression (3). It should be noted that the distance of the optical pulse passing through a transmitting laminate (a laminate of the first layer 23, the quantum well layer 24, and the second layer 25) 27 of the semiconductor saturable absorption mirror 20 is negligible.

$$L = \frac{d}{cos {θ}_{2}} = \frac{d}{\sqrt{1 - {sin}^{2} {θ}_{2}}} = \frac{d}{\sqrt{1 - {( \frac{{n}_{1}}{{n}_{2}} )}^{2} {sin}^{2} {θ}_{1}}} \qquad ( 3 )$$

If the group velocity dispersion value per unit length of the group velocity dispersion unit 30 is p, and the desired group velocity dispersion value is q, a distance necessary for obtaining the desired group velocity dispersion value q becomes q/p. Therefore, the required number of reflections RT_{g} is expressed as Expression (4).

$${RT}_{g} = \frac{q / p}{L} - 1 = \frac{q}{p} \frac{\sqrt{1 - {( \frac{{n}_{1}}{{n}_{2}} )}^{2} {sin}^{2} {θ}_{1}}}{d} - 1 \qquad ( 4 )$$

In this case, the length X of the group velocity dispersion unit 30 is expressed as Expression (5).

$$X = ( {RT}_{g} + 1 ) d tan {θ}_{2} = \frac{q}{p} \frac{{n}_{1}}{{n}_{2}} sin {θ}_{1} \qquad ( 5 )$$

If Expression (5) is modified, the group velocity dispersion value q obtained by the group velocity dispersion unit 30 is expressed as Expression (6).

$$q = \frac{{n}_{2}}{{n}_{1}} \frac{pX}{sin {θ}_{1}} \qquad ( 6 )$$

As will be understood from Expression (6), the thickness d of the group velocity dispersion unit 30 can be set as a parameter which does not affect the group velocity dispersion value q. Accordingly, when reflection loss in the semiconductor saturable absorption mirror 20 is negligible, it is possible to make the thickness d of the group velocity dispersion unit 30 small and to reduce the short optical pulse generator 100 in size. When reflection loss is not negligible, the thickness d of the group velocity dispersion unit 30 increases, thereby reducing the number of reflections in the semiconductor saturable absorption mirror 20.

Here, it is assumed that the wavelength of the optical pulse generated by the optical pulse generation unit 10 is 850 nm, the incidence angle θ1 is 0.1°, the medium before the optical pulse is incident on the group velocity dispersion unit 30 is air (n1=1), the material of the group velocity dispersion unit 30 is glass (BK7), and the thickness d of the group velocity dispersion unit 30 is 10 mm. The refractive index n2 of the group velocity dispersion unit 30 becomes 1.51 with respect to light of the wavelength of 850 nm. The group velocity dispersion value per mm of the group velocity dispersion unit 30 becomes 4.7×10⁻²⁹ s²/mm with respect to light of the wavelength 850 nm. If the desired group velocity dispersion value q is 1×10⁻²⁴ s², the number of reflections RTg 2127 from Expression (4). The length X of the group velocity dispersion unit 30≅2.5 cm from Expression (5).

As described above, when the length X of the group velocity dispersion unit 30 is 2.5 cm, n1 is 1, and n2 is 1.51, and when the incidence angle θ1 is changed, the relationship between the incidence angle θ1 and the group velocity dispersion value q is as shown in FIG. 10 from Expression (6). From FIG. 10, it is understood that the incidence angle θ1 is changed, whereby the group velocity dispersion value is variable in a range of about 1.77×10⁻²⁷ S² to 1×10⁻²⁴ s².

Next, if a chirp quantity applied each time the optical pulse is reflected by the semiconductor saturable absorption mirror 20 is r, and a desired chirp quantity is s, the required number of reflections RTs is expressed as Expression (7). However, it is assumed that the influence of the incidence angle is negligible.

$${RT}_{s} = \frac{s}{r} - 1 \qquad ( 7 )$$

Here, if RTs=RTg, r is expressed as Expression (8) from Expression (4) and Expression (7).

$$r = \frac{s}{\frac{q}{p} \frac{\sqrt{1 - {( \frac{{n}_{1}}{{n}_{2}} )}^{2} {sin}^{2} {θ}_{1}}}{d}} \qquad ( 8 )$$

The chirp quantity r is adjusted to satisfy Expression (8). As a method of adjusting the chirp quantity r, for example, a method of adjusting the number of wells of the quantum well layer 24 of the semiconductor saturable absorption mirror 20, a method of adjusting a bias to be applied to the semiconductor saturable absorption mirror 20 by the electrodes 60 and 62, a method of adjusting the number of reflections of the optical pulse in the semiconductor saturable absorption mirror 20, or the like may be used.

### 3. Terahertz Wave Generator

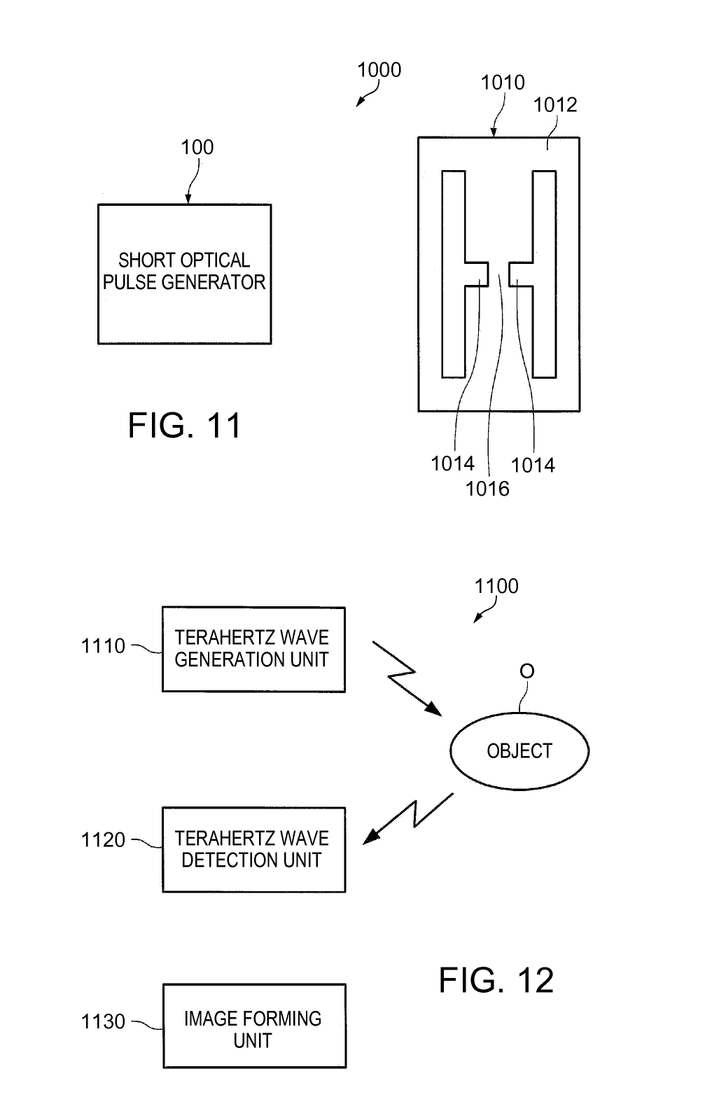

Next, a terahertz wave generator 1000 of the embodiment will be described referring to the drawings. FIG. 11 is a diagram showing the configuration of the terahertz wave generator 1000 according to the embodiment.

As shown in FIG. 11, the terahertz wave generator 1000 includes the short optical pulse generator according to the embodiment of the invention, and a photoconductive antenna 1010. Here, description will be provided as to a case where the short optical pulse generator 100 is used as the short optical pulse generator according to the embodiment of the invention.

The short optical pulse generator 100 generates a short optical pulse (for example, the optical pulse P4 shown in FIG. 6) which is excitation light. The pulse width of the short optical pulse generated by the short optical pulse generator 100 is, for example, equal to or greater than 1 fs and equal to or less than 800 fs.

The photoconductive antenna 1010 generates a terahertz wave when irradiated with the short optical pulse generated by the short optical pulse generator 100. It should be noted that the terahertz wave refers to an electromagnetic wave having a frequency equal to or greater than 100 GHz and equal to or less than 30 THz, and in particular, an electromagnetic wave having a frequency equal to or greater than 300 GHz and equal to or less than 3 THz.

In the example shown in the drawing, the photoconductive antenna 1010 is a dipole photoconductive antenna (PCA). The photoconductive antenna 1010 has a substrate 1012 which is a semiconductor substrate, and a pair of electrodes 1014 which are provided on the substrate 1012 and are arranged to face each other through a gap 1016. If the optical pulse is irradiated between the electrodes 1014, the photoconductive antenna 1010 generates the terahertz wave.

The substrate 1012 has, for example, a semi-insulating GaAs (SI-GaAs) substrate, and a low-temperature growth GaAs (LT-GaAs) layer which is provided on the SI-GaAs substrate. The material for the electrodes 1014 is, for example, Au. The distance between the pair of electrodes 1014 is not particularly limited and is appropriately set according to a condition. The distance between the pair of electrodes 1014 is, for example, equal to or greater than 1 μm and equal to or less than 10 μm.

In the terahertz wave generator 1000, first, the short optical pulse generator 100 generates the short optical pulse and emits the short optical pulse toward the gap 1016 of the photoconductive antenna 1010. The gap 1016 of the photoconductive antenna 1010 is irradiated with the short optical pulse emitted from the short optical pulse generator 100. In the photoconductive antenna 1010, the gap 1016 is irradiated with the short optical pulse, whereby a free electron is excited. Then, the free electron is accelerated by applying a voltage between the electrodes 1014. With this, the terahertz wave is generated.

### 4. Imaging Apparatus

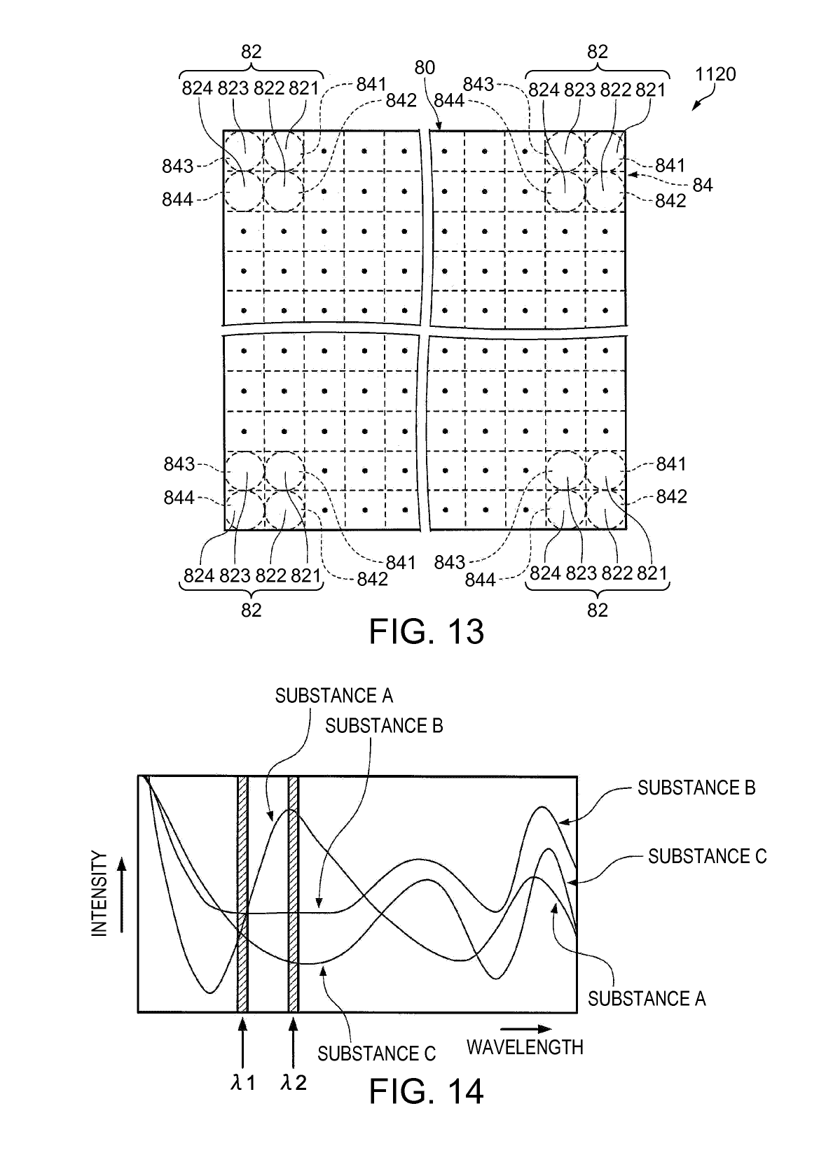

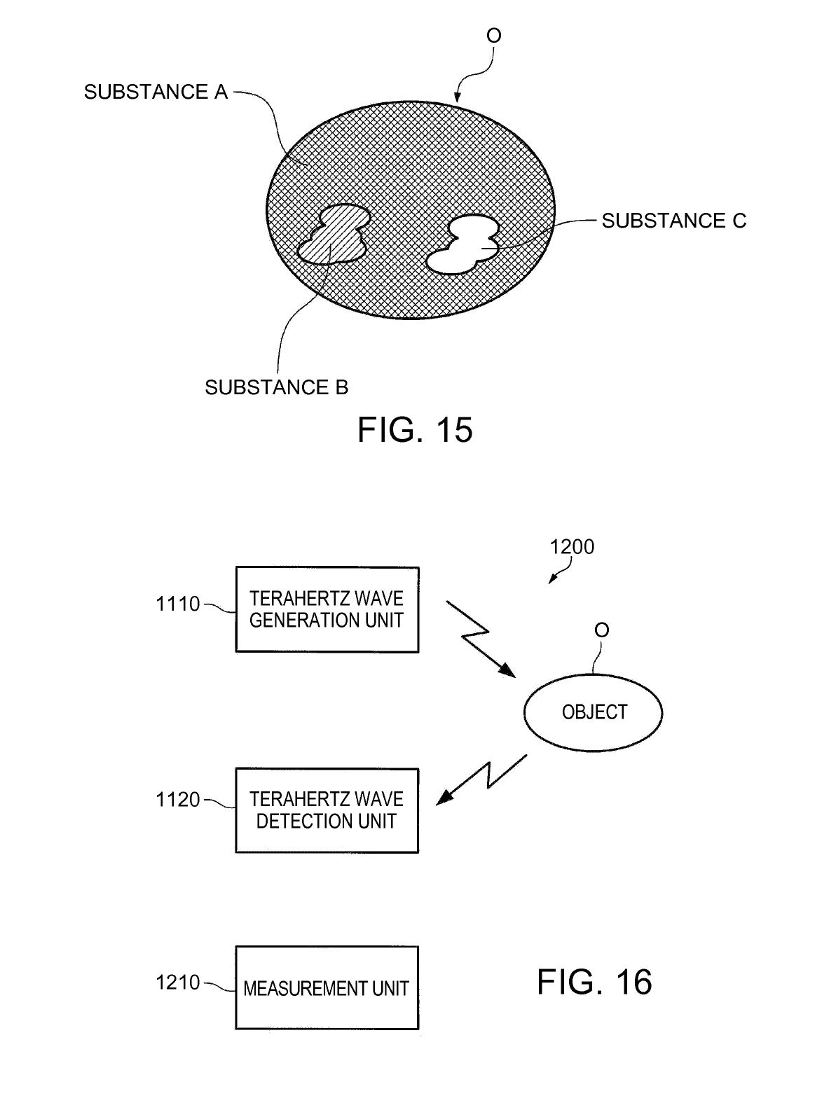

Next, an imaging apparatus 1100 according to the embodiment will be described referring to the drawings. FIG. 12 is a block diagram showing the imaging apparatus 1100 according to the embodiment. FIG. 13 is a plan view schematically showing a terahertz wave detection unit 1120 of the imaging apparatus 1100 according to the embodiment. FIG. 14 is a graph showing a spectrum in a terahertz band of an object. FIG. 15 is a diagram of an image representing the distribution of substances A, B, and C of the object.

As shown in FIG. 12, the imaging apparatus 1100 includes a terahertz wave generation unit 1110 which generates a terahertz wave, a terahertz wave detection unit 1120 which detects the terahertz wave emitted from the terahertz wave generation unit 1110 and transmitted through an object O or the terahertz wave reflected by the object O, and an image forming unit 1130 which generates the image of the object O, that is, image data, based on the detection result of the terahertz wave detection unit 1120.

As the terahertz wave generation unit 1110, the terahertz wave generator according to the embodiment of the invention can be used. Here, description will be provided as to a case where the terahertz wave generator 1000 is used as the terahertz wave generator according to the embodiment of the invention.

As the terahertz wave detection unit 1120, as shown in FIG. 13, a terahertz wave detection unit including a filter 80 which transmits a terahertz wave having a target wavelength, and a detection unit 84 which detects the terahertz wave having the target wavelength transmitted through the filter 80 is used. As the detection unit 84, for example, a detection unit which converts the terahertz wave to heat and detects heat, that is, a detection unit which converts the terahertz wave to heat and detects the energy (intensity) of the terahertz wave is used. As the detection unit, for example, a piezoelectric sensor, a bolometer, or the like is used. It should be noted that the configuration of the terahertz wave detection unit 1120 is not limited to the above-described configuration.

The filter 80 has a plurality of pixels (unit filter unit) 82 arranged in a two-dimensional manner. That is, the pixels 82 are arranged in a matrix.

Each pixel 82 has a plurality of regions which transmit terahertz waves having different wavelengths, that is, a plurality of regions in which the wavelengths (hereinafter, also referred to as “transmitting wavelengths) of transmitting terahertz waves are different from one another. It should be noted that, in the configuration shown in the drawing, each pixel 82 has a first region 821, a second region 822, a third region 823, and a fourth region 824.

The detection unit 84 has a first unit detection unit 841, a second unit detection unit 842, a third unit detection unit 843, and a fourth unit detection unit 844 which are provided respectively corresponding to the first region 821, the second region 822, the third region 823, and the fourth region 824 of each pixel 82 of the filter 80. Each first unit detection unit 841, each second unit detection unit 842, each third unit detection unit 843, and each fourth unit detection unit 844 respectively convert the terahertz waves transmitted through the first region 821, the second region 822, the third region 823, and the fourth region 824 of each pixel 82 to heat and detect heat. With this, it is possible to reliably detect terahertz waves having four target wavelengths for each pixel 82.

Next, a use example of the imaging apparatus 1100 will be described.

First, it is assumed that an object O which is subjected to spectroscopic imaging has three substances A, B, and C. The imaging apparatus 1100 performs spectroscopic imaging of the object O. Here, as an example, it is assumed that the terahertz wave detection unit 1120 detects the terahertz wave reflected by the object O.

In each pixel 82 of the filter 80 of the terahertz wave detection unit 1120, the first region 821 and the second region 822 are used. When the transmitting wavelength of the first region 821 is λ1, the transmitting wavelength of the second region 822 is λ2, the intensity of a component of the wavelength λ1 of the terahertz wave reflected by the object O is α1, and the intensity of a component of the wavelength λ2 of the terahertz wave reflected by the object O is α2, the transmitting wavelength λ1 of the first region 821 and the transmitting wavelength λ2 of the second region 822 are set such that the difference (α2−α1) between the intensity α2 and the intensity α1 can be distinctively distinguished among the substance A, the substance B, and the substance C.

As shown in FIG. 14, in the substance A, the difference (α2−α1) between the intensity α2 of the component of the wavelength λ2 and the intensity α1 of the component of the wavelength λ1 of the terahertz wave reflected by the object O has a positive value. In the substance B, the difference (α2−α1) between the intensity α2 and the intensity α1 becomes zero. In the substance C, the difference (α2−α1) between the intensity α2 and the intensity α1 has a negative value.

When performing spectroscopic imaging of the object O by the imaging apparatus 1100, first, the terahertz wave is generated by the terahertz wave generation unit 1110, and the object O is irradiated with the terahertz wave. Then, the terahertz wave reflected by the object O is detected by the terahertz wave detection unit 1120 as α1 and α2. The detection result is transmitted to the image forming unit 1130. It should be noted that the irradiation of the object O with the terahertz wave and the detection of the terahertz wave reflected by the object O are performed for the entire object O.

The image forming unit 1130 obtains the difference (α2−α1) between the intensity α2 of a component of the wavelength λ2 of the terahertz wave transmitted through the second region 822 of the filter 80 and the intensity α1 of a component of the wavelength λ1 of the terahertz wave transmitted through the first region 821 based on the detection result. Then, a region of the object O where the difference has a positive value, a region where the difference becomes zero, and a region where the difference has a negative value are determined to be respectively the substance A, the substance B, and the substance C and specified.

In the image forming unit 1130, as shown in FIG. 15, image data of an image representing the distribution of the substances A, B, and C of the object O is created. Image data is transmitted from the image forming unit 1130 to a monitor (not shown), and the image representing the distribution of the substances A, B, and C of the object O is displayed on the monitor. In this case, for example, a region of the object O where the substance A is distributed, a region where the substance B is distributed, and a region where the substance C is distributed are respectively displayed black, gray, and white in a color-coded manner. In the imaging apparatus 1100, as described above, it is possible to simultaneously perform the identification of each substance constituting the object O and the distribution measurement of each substance.

The purpose of the imaging apparatus 1100 is not limited to the above-described purpose, and for example, a person may be irradiated with the terahertz wave, the terahertz wave transmitted through or reflected by the person may be detected, and processing may be performed in the image forming unit 1130, thereby performing determination about whether or not the person carries a gun, a knife, an illegal drug, or the like.

### 5. Measurement Apparatus

Next, a measurement apparatus 1200 according to the embodiment will be described referring to the drawings. FIG. 16 is a block diagram showing the measurement apparatus 1200 according to the embodiment. In the measurement apparatus 1200 according to the embodiment described below, the members having the same functions as the component members of the above-described imaging apparatus 1100 are represented by the same reference numerals, and detailed description thereof will not be repeated.

As shown in FIG. 16, the measurement apparatus 1200 includes a terahertz wave generation unit 1110 which generates a terahertz wave, a terahertz wave detection unit 1120 which detects the terahertz wave emitted from the terahertz wave generation unit 1110 and transmitted through an object O or the terahertz wave reflected by the object O, and a measurement unit 1210 which measures the object O based on the detection result of the terahertz wave detection unit 1120.

Next, a use example of the measurement apparatus 1200 will be described. When performing spectroscopic measurement of the object O by the measurement apparatus 1200, first, the terahertz wave is generated by the terahertz wave generation unit 1110, and the object O is irradiated with the terahertz wave. Then, the terahertz wave transmitted through the object O or the terahertz wave reflected by the object O is detected by the terahertz wave detection unit 1120. The detection result is transmitted to the measurement unit 1210. It should be noted that the irradiation of the object O with the terahertz wave and the detection of the terahertz wave transmitted through the object O or the terahertz wave reflected by the object O are performed for the entire object O.

The measurement unit 1210 understands the intensities of the terahertz waves transmitted through the first region 821, the second region 822, the third region 823, and the fourth region 824 of each pixel 82 of the filter 80 from the detection result, and analyzes the components of the object O, the distribution of the components, or the like.

### 6. Camera

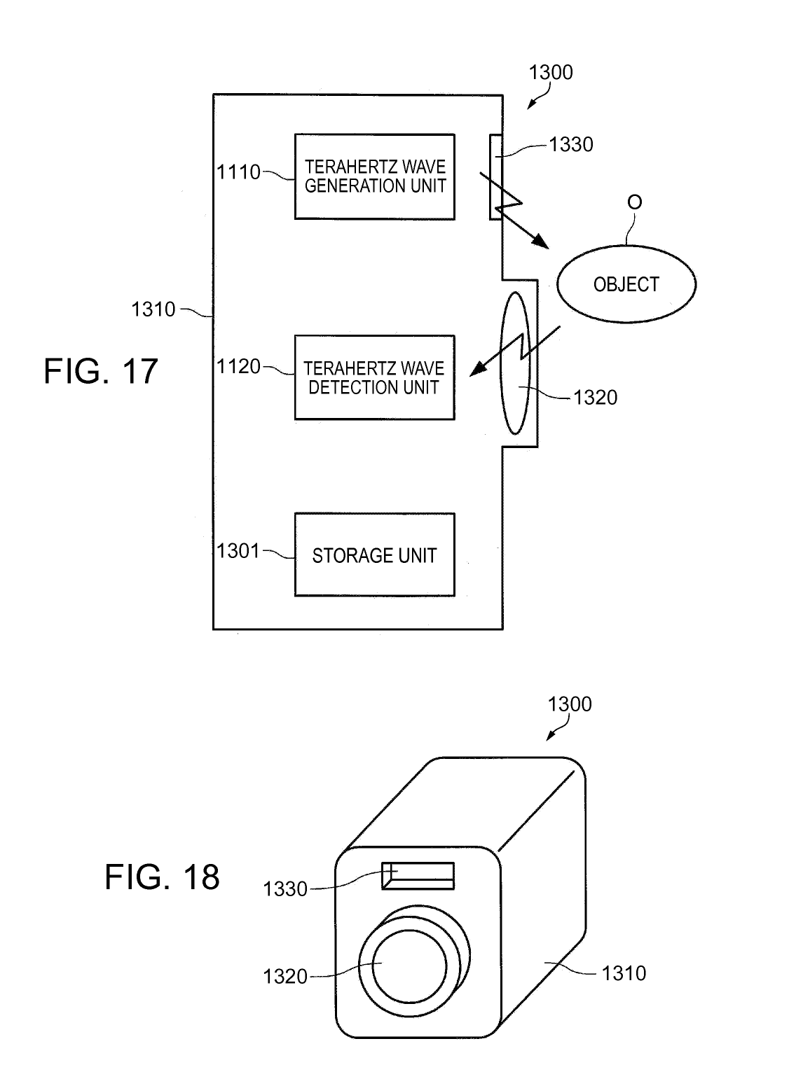

Next, a camera 1300 according to the embodiment will be described referring to the drawings. FIG. 17 is a block diagram showing the camera 1300 according to the embodiment. FIG. 18 is a perspective view schematically showing the camera 1300 according to the embodiment. In the camera 1300 according to the embodiment described below, the members having the same functions as the component members of the above-described imaging apparatus 1100 are represented by the same reference numerals, and detailed description thereof will not be repeated.

As shown in FIGS. 17 and 18, the camera 1300 includes a terahertz wave generation unit 1110 which generates a terahertz wave, a terahertz wave detection unit 1120 which detects the terahertz wave emitted from the terahertz wave generation unit 1110 and reflected by an object O or the terahertz wave transmitted through the object O, and a storage unit 1301. The respective units 1110, 1120, and 1301 are housed in a housing 1310 of the camera 1300. The camera 1300 includes a lens (optical system) 1320 which converges (images) the terahertz wave reflected by the object O to (on) the terahertz wave detection unit 1120, and a window 1330 through which the terahertz wave generated by the terahertz wave generation unit 1110 is emitted to the outside of the housing 1310. The lens 1320 or the window 1330 is made of a member, such as silicon, quartz, or polyethylene, which transmits or refracts the terahertz wave. It should be noted that the window 1330 may have a configuration in which only an opening, such as a slit, is provided.

Next, a use example of the camera 1300 will be described. When imaging the object O by the camera 1300, first, the terahertz wave is generated by the terahertz wave generation unit 1110, and the object O is irradiated with the terahertz wave. Then, the terahertz wave reflected by the object O is converged to (imaged on) the terahertz wave detection unit 1120 by the lens 1320 and detected. The detection result is transmitted to and stored in the storage unit 1301. It should be noted that the irradiation of the object O with the terahertz wave and the detection of the terahertz wave reflected by the object O are performed for the entire object O. The detection result may be transmitted to an external apparatus, for example, a personal computer. The personal computer can perform respective kinds of processing based on the detection result.

The above-described embodiment and the modification examples are an example and are not intended to limit the invention. For example, the embodiment and the modification examples may be appropriately combined.

The invention includes configurations which are substantially the same as the configurations described in the embodiment (for example, configurations having the same functions, methods, and results, or configurations having the same purposes and effects). The invention includes configurations in which non-essential parts of the configurations described in the embodiment are replaced. The invention includes configurations which exhibit the same functional effects as the configurations described in the embodiment, or configurations capable of achieving the same objects. The invention includes configurations in which known techniques are added to the configurations described in the embodiment.

The entire disclosure of Japanese Patent Application No. 2013-261359, filed Dec. 18, 2013 is expressly incorporated by reference herein.

What is claimed is:

1. A short optical pulse generator comprising:
an optical pulse generation unit which generates an optical pulse;
a semiconductor saturable absorption mirror which has a multilayer film mirror and a quantum well structure and reflects the optical pulse; and
a group velocity dispersion unit which produces a group velocity difference according to wavelength in the optical pulse reflected by the semiconductor saturable absorption mirror.

2. The short optical pulse generator according to claim 1, further comprising:
an electrode which applies a reverse bias to the semiconductor saturable absorption mirror.

3. The short optical pulse generator according to claim 1,
wherein two semiconductor saturable absorption mirrors are provided,
the group velocity dispersion unit is provided to be sandwiched between the two semiconductor saturable absorption mirrors, and
the optical pulse incident on the group velocity dispersion unit is reflected by the two semiconductor saturable absorption mirrors multiple times and travels in the group velocity dispersion unit.

4. The short optical pulse generator according to claim 1, further comprising:
a variable mechanism which changes the incidence angle of the optical pulse to the semiconductor saturable absorption mirror.

5. The short optical pulse generator according to claim 1, further comprising:
a collimator lens which converts the optical pulse incident on the group velocity dispersion unit to parallel light.

6. The short optical pulse generator according to claim 1,
wherein the group velocity dispersion unit is a glass substrate.

7. A terahertz wave generator comprising:
the short optical pulse generator according to claim 1;
a photoconductive antenna which generates a terahertz wave when irradiated with a short optical pulse generated by the short optical pulse generator.

8. A terahertz wave generator comprising:
the short optical pulse generator according to claim 2;
a photoconductive antenna which generates a terahertz wave when irradiated with a short optical pulse generated by the short optical pulse generator.

9. A terahertz wave generator comprising:
the short optical pulse generator according to claim 3;
a photoconductive antenna which generates a terahertz wave when irradiated with a short optical pulse generated by the short optical pulse generator.

10. A terahertz wave generator comprising:
the short optical pulse generator according to claim 4;
a photoconductive antenna which generates a terahertz wave when irradiated with a short optical pulse generated by the short optical pulse generator.

11. A camera comprising:
the short optical pulse generator according to claim 1;
a photoconductive antenna which generates a terahertz wave when irradiated with a short optical pulse generated by the short optical pulse generator;
a terahertz wave detection unit which detects the terahertz wave emitted from the photoconductive antenna and transmitted through an object or the terahertz wave reflected by the object; and
a storage unit which stores the detection result of the terahertz wave detection unit.

12. A camera comprising:
the short optical pulse generator according to claim 2;
a photoconductive antenna which generates a terahertz wave when irradiated with a short optical pulse generated by the short optical pulse generator;
a terahertz wave detection unit which detects the terahertz wave emitted from the photoconductive antenna and transmitted through an object or the terahertz wave reflected by the object; and
a storage unit which stores the detection result of the terahertz wave detection unit.

13. A camera comprising:
the short optical pulse generator according to claim 3;
a photoconductive antenna which generates a terahertz wave when irradiated with a short optical pulse generated by the short optical pulse generator;
a terahertz wave detection unit which detects the terahertz wave emitted from the photoconductive antenna and transmitted through an object or the terahertz wave reflected by the object; and
a storage unit which stores the detection result of the terahertz wave detection unit.

14. A camera comprising:
the short optical pulse generator according to claim 4;
a photoconductive antenna which generates a terahertz wave when irradiated with a short optical pulse generated by the short optical pulse generator;
a terahertz wave detection unit which detects the terahertz wave emitted from the photoconductive antenna and transmitted through an object or the terahertz wave reflected by the object; and
a storage unit which stores the detection result of the terahertz wave detection unit.

15. An imaging apparatus comprising:
the short optical pulse generator according to claim 1;
a photoconductive antenna which generates a terahertz wave when irradiated with a short optical pulse generated by the short optical pulse generator;
a terahertz wave detection unit which detects the terahertz wave emitted from the photoconductive antenna and transmitted through an object or the terahertz wave reflected by the object; and
an image forming unit which forms the image of the object based on the detection result of the terahertz wave detection unit.

16. An imaging apparatus comprising:
the short optical pulse generator according to claim 2;
a photoconductive antenna which generates a terahertz wave when irradiated with a short optical pulse generated by the short optical pulse generator;
a terahertz wave detection unit which detects the terahertz wave emitted from the photoconductive antenna and transmitted through an object or the terahertz wave reflected by the object; and
an image forming unit which forms the image of the object based on the detection result of the terahertz wave detection unit.

17. An imaging apparatus comprising:
the short optical pulse generator according to claim 3;
a photoconductive antenna which generates a terahertz wave when irradiated with a short optical pulse generated by the short optical pulse generator;
a terahertz wave detection unit which detects the terahertz wave emitted from the photoconductive antenna and transmitted through an object or the terahertz wave reflected by the object; and
an image forming unit which forms the image of the object based on the detection result of the terahertz wave detection unit.

18. A measurement apparatus comprising:
the short optical pulse generator according to claim 1;
a photoconductive antenna which generates a terahertz wave when irradiated with a short optical pulse generated by the short optical pulse generator;
a terahertz wave detection unit which detects the terahertz wave emitted from the photoconductive antenna and transmitted through an object or the terahertz wave reflected by the object; and
a measurement unit which measures the object based on the detection result of the terahertz wave detection unit.

19. A measurement apparatus comprising:
the short optical pulse generator according to claim 2;
a photoconductive antenna which generates a terahertz wave when irradiated with a short optical pulse generated by the short optical pulse generator;
a terahertz wave detection unit which detects the terahertz wave emitted from the photoconductive antenna and transmitted through an object or the terahertz wave reflected by the object; and
a measurement unit which measures the object based on the detection result of the terahertz wave detection unit.

20. A measurement apparatus comprising:
the short optical pulse generator according to claim 3;
a photoconductive antenna which generates a terahertz wave when irradiated with a short optical pulse generated by the short optical pulse generator;
a terahertz wave detection unit which detects the terahertz wave emitted from the photoconductive antenna and transmitted through an object or the terahertz wave reflected by the object; and
a measurement unit which measures the object based on the detection result of the terahertz wave detection unit.
